(19) United States
(12) Patent Application Publication
(10) Pub. No.: US 2024/0360551 A1
(43) Pub. Date: Oct. 31, 2024

(54) HEATING MODULE AND PROGRAM CONTROL METHOD FOR PUMPING LINE OF SEMICONDUCTOR PROCESSING TOOL

(71) Applicant: Taiwan Semiconductor Manufacturing Company, Hsinchu (TW)

(72) Inventors: Sheng-chun Yang, Tainan (TW); Yi-Ming Lin, Tainan (TW); Chun Chang, Tainan (TW); Che Kang Liu, Tainan (TW); Kaijun Jan, Tainan (TW); Xuan-Yang Zheng, Tainan (TW); Tzu-Chuan Chao, Tainan (TW); Weigang Wu, Kaohsiung (TW); Chih-Yuan Wang, Tainan (TW); Ren-Jyue Wang, Tainan (TW)

(21) Appl. No.: 18/141,073

(22) Filed: Apr. 28, 2023

(51) Int. Cl. C23C 16/44; C23C 16/455; C23C 16/458; C23C 16/52

(52) U.S. Cl. CPC C23C 16/4412; C23C 16/45561; C23C 16/4583; C23C 16/52

(57) ABSTRACT

A semiconductor processing tool includes: a process chamber into which a semiconductor wafer is loaded; a support for securing the wafer loaded into the chamber tool; an inlet which introduces a first gas into the chamber for processing the wafer; and an exhaust system that exhausts gas from the chamber. The exhaust system includes: a first line coupled to the chamber to exhaust gas from the chamber; and a pump to draw gas through the first line from the chamber. The tool further includes a heating module having: a second line coupled to the first and a supply of a second gas, the second gas being flowed through the second line from the supply into the first line; and a heating element contained in the second line, the heating element heating the second gas in the second line before the second gas is flowed into the first line.

### BACKGROUND

The following relates to the semiconductor arts, and in particular, to a heating module and/or method for a vacuum pumping line of a semiconductor processing tool, for example, without limitation, a sub-atmospheric chemical vapor deposition (SACVD) tool, or more generally a chemical vapor deposition (CVD) tool.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features as shown in the accompanying figures may be arbitrarily increased or reduced for clarity of discussion.

FIGS. 1A and 1B are diagrammatic illustrations showing a semiconductor processing tool in accordance with some embodiments disclosed herein.

FIG. 2 is a diagrammatic illustration showing a heating module in accordance with some embodiments disclosed herein, for use with the semiconductor processing tool shown in FIGS. 1A and 1B.

FIG. 3 is a diagrammatic illustration showing a heating element in accordance with some embodiments disclosed herein, for use with the heating module shown in FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Further, it is to be understood that when an element is referred to as being “connected to” or “coupled to” another element, it may be directly connected to or coupled to the other element, or one or more intervening elements may be present. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “left,” “right,” “side,” “back,” “rear,” “behind,” “front,” “beneath,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “about” may include any numerical value that can vary without changing the basic function of that value. When used with a range, “about” also discloses the range defined by the absolute values of the two endpoints, for example, “about 2 to about 4” also discloses the range “from 2 to 4.” The term “about” may refer to plus or minus 10% of the indicated number.

The manufacturing of semiconductor devices is generally a multi-step process with various process steps being carried out using various semiconductor processing tools suitably equipped and/or provisioned for executing respective steps of the fabrication process. In accordance with some suitable embodiments disclosed herein, a semiconductor processing tool includes a process chamber and an exhaust system operatively connected and/or coupled thereto. Suitably, the exhaust system may include one or more pumps, values, tubes and/or pipes operatively coupled to the process chamber which cooperate to, for example, selectively produce and/or maintain desired vacuum or other pressure conditions within the process chamber and/or selectively evacuate or otherwise remove gases (for example, including residual process and/or carrier gases, unwanted byproducts, contaminates, particulates and/or the like which are suspended or otherwise contained therein) from the process chamber.

In practice, one or more semiconductor substrates and/or wafers may be loaded into the process chamber of the semiconductor processing tool to conduct one or more process steps in connection with the fabrication and/or manufacturing of semiconductor devices. Various semiconductor manufacturing process operations, for example, such material deposition processes, etching processes, cleaning processes and/or other suitable processes, may be performed in the process chamber on semiconductor substrates and/or wafers contained therein to fabricate desired semiconductor devices. Suitably, the semiconductor processing tool may be used to perform various types of CVD, for example, SACVD, or other material deposition processes on semiconductor substrates and/or wafers contained in the process chamber. In some suitable embodiments, the semiconductor processing tool may be used to conduct material removal processes, for example, such as etching, to remove material from semiconductor substrates and/or wafers contained within the process chamber. In some suitable embodiments, the semiconductor processing tool may be used to conduct cleaning processes, for example, to remove unwanted byproducts and/or contaminates from the semiconductor substrate or wafer and/or from the process chamber. In some suitable embodiments, the semiconductor processing tool is a CVD tool, a SACVD tool, a physical vapor deposition (PVD) tool, a decoupled plasma nitridation (DPN) tool, an atomic layer deposition (ALD) tool, a low pressure CVD (LPCVD) tool, an ultrahigh vacuum CVD (UHVCVD) tool, a reduced pressure CDV (RPCVD) tool, or other suitable material deposition tool, an etching tool, a cleaning tool and/or the like.

In practice, some semiconductor fabrication processes are performed in the process chamber under vacuum or other selected pressure conditions. Accordingly, the exhaust system coupled to the process chamber may be used to generate the desired vacuum and/or pressure conditions within the process chamber. Moreover, while a fabrication process is being conducted within the process chamber, one or more semiconductor substrates or wafers may be supported on and/or selectively secured to one or more support surface, for example, utilizing one or more vacuum chucks or the like. In some suitable embodiments, the vacuum source for the process chamber may also be employed to generate a vacuum condition at the support surfaces. That is to say, the exhaust system may also be utilized as a vacuum source for one or more vacuum chucks housed in the process chamber.

In some suitable embodiments, the exhaust system is selectively utilized to draw, evacuate and/or otherwise remove gases, for example, including residual process and/or carrier gases, unwanted byproducts, contaminates, particulates and/or the like which may be suspended or otherwise contained therein, from the process chamber. In practice, process gases and/or carrier gas may be introduced into the process chamber during a fabrication process step and/or byproducts or other gases may be produced in the process chamber as a result of a fabrication process step. Suitably, the exhaust system may selectively exhaust such gases from the process chamber during or after a given fabrication process step.

In some suitable embodiments disclosed herein, a heating module is operatively coupled to the exhaust system of the semiconductor processing tool. Advantageously, the heating module inhibits and/or mitigates against an undesired depositing and/or build-up of contaminates within an exhaust pipe of the exhaust system by selectively flowing a heated gas into the exhaust pipe to maintain a temperature of gases flowing through the exhaust pipe at a desired level. For example, the heated gas may be nitrogen or another suitable inert gas. One advantage of the heating module is that it mitigates against the build-up of contaminates within the exhaust pipe, thereby keeping the pipe cleaner longer and/or keeping the exhaust pipe from becoming clogged and/or otherwise restrictive to gas flow therethrough. Another advantage is that an associated downtime of the semiconductor processing tool for cleaning purposes can be reduced (i.e., the cleaning cycle time may be increased) and an overall production through-put for the tool can be increased, for example, compared to other examples without the mitigation provided by the heating module disclosed herein.

Certain semiconductor fabrication processes, for example, CVD, SACVD, LPCVD, etc. involve the introduction of various precursors, chemicals, process gases, carrier gases and/or the like into the process chamber. In some cases, tetraethoxysilane (TEOS) may be utilized in some SACVD processes, a methyl-diethoxymethylsilane (mDEOS) precursor may be used in connection with the fabrication of extra-low k (ELK) semiconductor devices, an alpha-terpinene (ATRP) precursor may be used in some processes, and the like. For example, in a SACVD process using TEOS, certain generated volatile organics, including hydroxides (HO), and residual TEOS may be exhausted from the process chamber via the exhaust tube. Accordingly, in the exhaust pipeline, a hydrolysis reaction may occur resulting in a significant amount of TEOS polymerized polymer remaining and/or building-up in the exhaust pipeline. Generally, this reaction is a thermochemical reaction process, so that if the temperature within the exhaust pipeline is too high, unexpected and/or unwanted reactions may occur and if the temperature is too low, the hydrolysis may be accelerated. Accordingly, in accordance with some suitable embodiments herein, the heating module advantageously heats and/or maintains the gas flowing therefrom into the exhaust pipeline to and/or at a temperature in a range of between about 105° Celsius (C) and 110° C., inclusive.

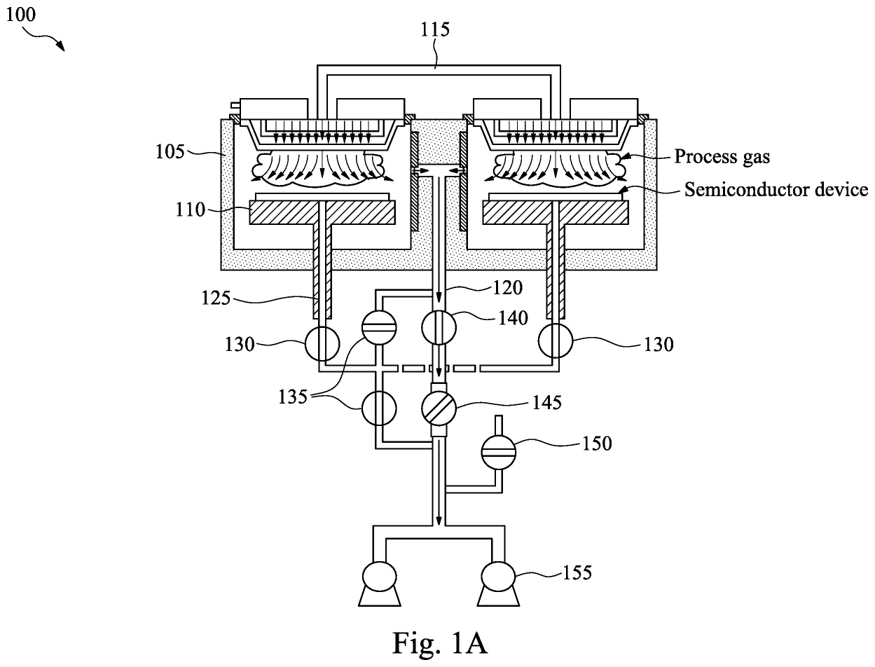

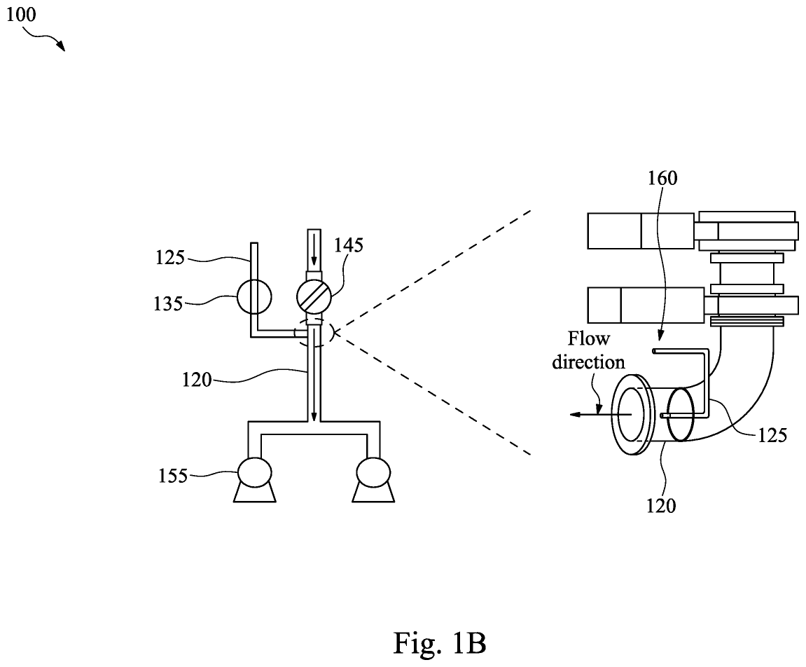

In accordance with some suitable embodiments disclosed herein, FIGS. 1A and 1B show diagrammatic illustrations of a semiconductor processing tool 100. The semiconductor processing tool may include a CVD tool, for example, such as a SACVD tool and/or the like. As shown in FIG. 1A, the semiconductor processing tool 100 may include two process chamber bodies 105, two vacuum chucks 110, a process gas inlet line 115, a main pumping line 120, two chuck vacuum lines 125, two chuck valves 130, two chuck bypass valves 135, an isolation valve 140, a throttle valve 145, a ballast valve 150, and two pumps 155. The description to follow will describe an implementation of a semiconductor processing tool 100 that includes two process chamber bodies 105, two vacuum chucks 110, a single process gas inlet line 115, a single main pumping line 120, two chuck vacuum lines 125, two chuck valves 130, two chuck bypass valves 135, a single isolation valve 140, a single throttle valve 145, a single ballast valve 150, and two pumps 155. In practice, a semiconductor processing tool 100 may include additional or fewer process chamber bodies 105, vacuum chucks 110, process gas inlet lines 115, main pumping lines 120, chuck vacuum lines 125, chuck valves 130, chuck bypass valves 135, isolation valves 140, throttle valves 145, ballast valves 150, and/or pumps 155.

Process chamber body 105 may include a housing that defines a process chamber for processing a semiconductor device (for example, a wafer) based on a function of the semiconductor processing tool 100. For example, the process chamber may be a CVD process chamber, SACVD chamber, and/or the like. Process chamber body 105 may be maintained at a pressure while the semiconductor device is being processed. For example, a pressure within process chamber body 105 may be maintained at less than about one atmosphere when the semiconductor device is processed. Process chamber body 105 may be sized and shaped to house vacuum chuck 110, components associated with process gas inlet line 115, the semiconductor device, and/or the like. Process chamber body 105 may be cylindrical in shape to aid in processing the semiconductor device, but may be other shapes, such as box-shaped, spherical, and/or the like. In some implementations, process chamber body 105 is constructed of a material or materials that are resistant to abrasion and/or corrosion caused by process gases, semiconductor processes, pressures, temperatures, and/or the like associated with the semiconductor processing tool. For example, process chamber body 105 may be constructed of stainless steel, aluminum, and/or the like. In some implementations, process chamber body 105 includes walls with thicknesses that provide a rigid structure capable of withstanding the semiconductor processes, the pressures, the temperatures, and/or the like associated with the semiconductor processing tool 100.

Vacuum chuck 110 may be provided within process chamber body 105 and may be sized and shaped to support and secure the semiconductor device during processing by the semiconductor processing tool 100. For example, vacuum chuck 110 may be circular shaped and may support all or a portion of a circular-shaped semiconductor device. Vacuum chuck 110 may secure the semiconductor device through the use of a vacuum. Vacuum chuck 110 may be connected to one or more plumbing fixtures (for example, chuck vacuum line 125) through which air is sucked from process chamber body 105 and through one or more openings in vacuum chuck 110 to create an air pressure differential in process chamber body 105. The air pressure differential includes a negative air pressure below the semiconductor device and a positive air pressure above the semiconductor device. The air pressure differential causes the semiconductor device to be forced against vacuum chuck 110 as the positive air pressure and the negative air pressure attempt to equalize in process chamber body 105. In some implementations, vacuum chuck 110 is constructed of a material or materials that are resistant to abrasion and/or corrosion caused by process gases, semiconductor processes, pressures, temperatures, and/or the like associated with the semiconductor processing tool 100. For example, vacuum chuck 110 may be constructed of stainless steel, aluminum, plated aluminum (for example, gold plated or nickel plated), and/or the like. In some implementations, vacuum chuck 110 includes a surface friction that retains the semiconductor device on a surface of vacuum chuck 110.

Process gas inlet line 115 may include one or more plumbing fixtures (for example, tubes, pipes, valves, and/or the like) through which a process gas is provided into process chamber body 105. The process gas may include a gas utilized to process the semiconductor device based on a function of the semiconductor processing tool 100. For example, the process gas may include silicon gas, argon, nitrogen, TEOS, mDEOS and/or the like. In some implementations, process gas inlet line 115 connects to both process chamber bodies 105 so that the process gas is delivered into process chamber bodies 105. Process gas inlet line 115 may couple with one or more mechanisms (for example, a gas-box, showerhead, blocker plate, etc.) that evenly disperse the process gas into process chamber bodies 105 and onto the semiconductor device (for example, as shown by the process gas clouds in FIG. 1A). Process gas inlet line 115 may be sized and shaped to provide a quantity of the process gas to process chamber bodies 105 so that the semiconductor processing tool 100 may process the semiconductor device. In some implementations, process gas inlet line 115 is constructed of a material or materials that are resistant to corrosion or damage caused by the process gas, a pressure associated with the process gas, and/or the like. For example, process gas inlet line 115 may be constructed of polyvinyl chloride (PVC), chlorinated PVC (CPVC), polyvinylidene difluoride (PVDF), polypropylene, polyethylene, and/or the like.

Main pumping line 120 may include one or more plumbing fixtures (for example, tubes, pipes, valves, and/or the like) through which the process gas is removed from process chamber bodies 105 after processing of the semiconductor device. Main pumping line 120 may connect to pump 155 and pump 155 may suck the process gas and processing byproducts from process chamber bodies 105 via main pumping line 120. Process gas inlet line 115 may be sized and shaped to provide a quantity of the process gas to process chamber bodies 105 so that the semiconductor processing tool 100 may process the semiconductor device. In some implementations, main pumping line 120 is constructed of a material or materials that are resistant to corrosion or damage caused by the process gas, the pressure associated with the process gas, and/or the like. For example, main pumping line 120 may be constructed of PVC, CPVC, PVDF, polypropylene, polyethylene, and/or the like. Further details of main pumping line 120 are provided below in connection with FIG. 1B.

Chuck vacuum line 125 may include one or more plumbing fixtures (for example, tubes, pipes, valves, and/or the like) through which air is sucked from process chamber body 105 and through one or more openings in vacuum chuck 110 to create an air pressure differential in process chamber body 105. The air pressure differential includes a negative air pressure below the semiconductor device and a positive air pressure above the semiconductor device. The air pressure differential causes the semiconductor device to be forced against vacuum chuck 110 as the positive air pressure and the negative air pressure attempt to equalize in process chamber body 105. In some implementations, chuck vacuum line 125 connects to main pumping line 120, and the air is sucked through chuck vacuum line 125 via pump 155 sucking the process gas and processing byproducts from process chamber bodies 105 via main pumping line 120. In some implementations, chuck vacuum line 125 is constructed of a material or materials that are resistant to corrosion or damage caused by the process gas, the air pressure differential, and/or the like. For example, chuck vacuum line 125 may be constructed of PVC, CPVC, PVDF, polypropylene, polyethylene, and/or the like. Further details of chuck vacuum line 125 are provided below in connection with FIG. 1B. In some suitable embodiments, the vacuum chuck 110 may be provided with a heater for selectively heating the semiconductor device secured thereto in connection with the semiconductor fabrication process being conducted.

Chuck valve 130 may include a device that regulates, directs, or controls a flow of a fluid (for example, a gas) by opening, closing, or partially obstructing various passageways. For example, chuck valve 130 may connect to chuck vacuum line 125 and may control a level of a vacuum (for example, the negative air pressure below the semiconductor device) applied to vacuum chuck 110 by pump 155 via chuck vacuum line 125. In some implementations, chuck valve 130 is constructed of a material or materials that are resistant to corrosion or damage caused by the process gas, the air pressure differential, and/or the like. For example, one or more components of chuck valve 130 may be constructed of steel, aluminum, PVC, CPVC, PVDF, polypropylene, polyethylene, and/or the like.

Chuck bypass valve 135 may include a device that regulates, directs, or controls a flow of a fluid (for example, a gas) by opening, closing, or partially obstructing various passageways. For example, chuck bypass valve 135 may connect to chuck vacuum line 125 and may control whether chuck vacuum line 125 connects to main pumping line 120 at a first location (for example, upstream of isolation valve 140 and throttle valve 145) or a second location (for example, downstream of throttle valve 145). In some implementations, chuck bypass valve 135 is constructed of a material or materials that are resistant to corrosion or damage caused by the process gas, the air pressure differential, and/or the like. For example, one or more components of chuck bypass valve 135 may be constructed of steel, aluminum, PVC, CPVC, PVDF, polypropylene, polyethylene, and/or the like.

Isolation valve 140 may include a device that regulates, directs, or controls a flow of a fluid (for example, a gas) by opening, closing, or partially obstructing various passageways. For example, isolation valve 140 may connect to main pumping line 120 and may stop the flow of the process gas through main pumping line 120 (for example, for maintenance purposes, safety purposes, and/or the like). In some implementations, isolation valve 140 is constructed of a material or materials that are resistant to corrosion or damage caused by the process gas, the air pressure differential, and/or the like. For example, one or more components of isolation valve 140 may be constructed of steel, aluminum, PVC, CPVC, PVDF, polypropylene, polyethylene, and/or the like.

Throttle valve 145 may include a device that regulates, directs, or controls a flow of a fluid (for example, a gas) by opening, closing, or partially obstructing various passageways. For example, throttle valve 145 may connect to main pumping line 120 and may control a level of a vacuum applied to main pumping line 120 by pump 155. In some implementations, throttle valve 145 is constructed of a material or materials that are resistant to corrosion or damage caused by the process gas, the air pressure differential, and/or the like. For example, one or more components of throttle valve 145 may be constructed of steel, aluminum, PVC, CPVC, PVDF, polypropylene, polyethylene, and/or the like.

Ballast valve 150 may include a device that regulates, directs, or controls a flow of a fluid (for example, a gas) by opening, closing, or partially obstructing various passageways. For example, ballast valve 150 may connect to main pumping line 120 and may prevent pump from attaining a highest vacuum level achievable by pump 155. In some implementations, ballast valve 150 is constructed of a material or materials that are resistant to corrosion or damage caused by the process gas, the air pressure differential, and/or the like. For example, one or more components of ballast valve 150 may be constructed of steel, aluminum, PVC, CPVC, PVDF, polypropylene, polyethylene, and/or the like.

Pump 155 may include a device that removes a fluid (for example, a gas) from a sealed volume in order to achieve a partial vacuum. For example, pump 155 may connect to main pumping line 120, and may remove the process gas, the processing byproduct, and/or the like from main pumping line 120. In some implementations, pump 155 is constructed of a material or materials that are resistant to corrosion or damage caused by the process gas, the air pressure differential, and/or the like. For example, one or more components of pump 155 may be constructed of steel, aluminum, PVC, CPVC, PVDF, polypropylene, polyethylene, and/or the like. In some implementations, the semiconductor processing tool 100 may include a controller (not shown) that controls (for example, opens, closes, partially opens, partially closes, and/or the like) chuck valves 130, chuck bypass valves 135, isolation valves 140, throttle valves 145, and/or ballast valves 150, and that controls (for example, turns on or off) pumps 155.

In some implementations, as shown to the left in FIG. 1B, chuck vacuum line 125 may connect to main pumping line 120 downstream from throttle valve 145. Alternatively, or additionally, chuck vacuum line 125 may connect to main pumping line 120 upstream of isolation valve 140 and throttle valve 145. As shown to the right in FIG. 1B, a portion of chuck vacuum line 125 may be provided within main pumping line 120. As indicated by reference number 160, an orientation of a portion of main pumping line 120 (for example, the portion of main pumping line 120 where chuck vacuum line 125 is provided) may be substantially parallel to an orientation of a portion of chuck vacuum line 125 (for example, the portion where air exits chuck vacuum line 125). As further shown in FIG. 1B, the orientation of the portion of main pumping line 120 and the orientation of the portion of chuck vacuum line 125 may be parallel to a flow direction (for example, right to left in FIG. 1B) of the process gas through main pumping line 120.

Prior arrangements orient chuck vacuum line 125 at an angle of approximately ninety degrees to an orientation of main pumping line 120 and to the flow direction. These prior arrangements reduce the flow of the process gas in the flow direction through main pumping line 120 and cause processing byproducts from chuck vacuum line 125 to be deposited at an angle of approximately ninety degrees in main pumping line 120. This causes main pumping line 120 to be increasingly lined with the processing byproducts, which reduces and/or restricts airflow through main pumping line 120. Conversely, the parallel arrangement of the orientation of the portion of main pumping line 120 and the orientation of the portion of chuck vacuum line 125 does not reduce the flow of the process gas in the flow direction through main pumping line 120. Thus, the parallel arrangement prevents buildup of processing byproducts on interior walls of main pumping line 120.

As indicated above, FIGS. 1A and 1B are provided merely as one or more examples. Other examples may differ from what is described with regard to FIGS. 1A and 1B.

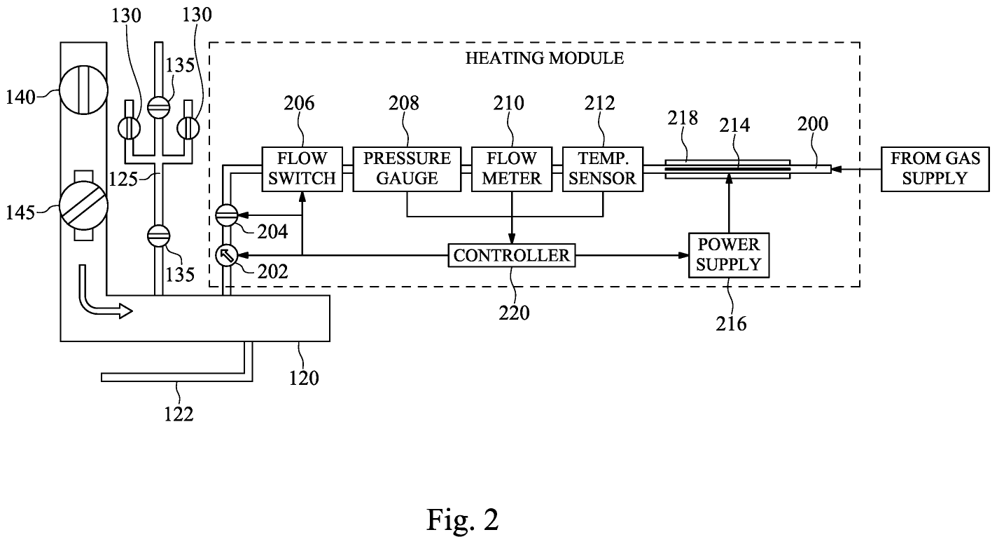

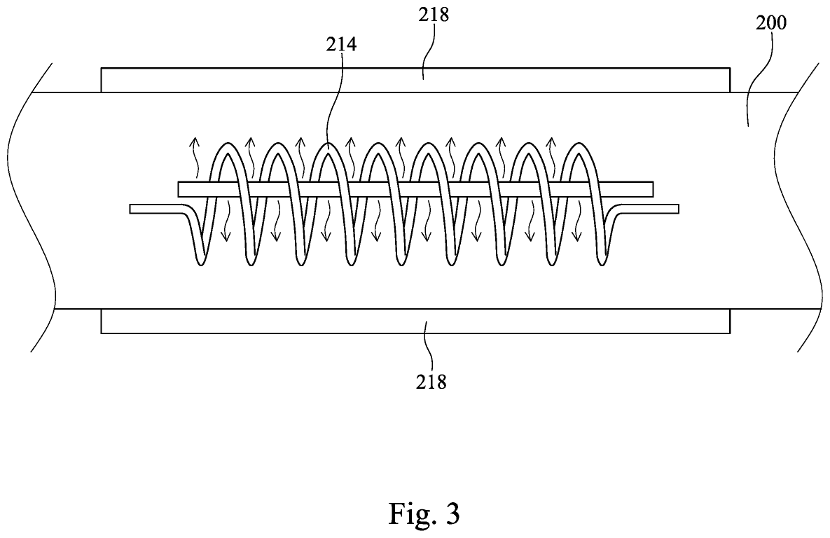

With reference now to FIG. 2, there is shown a heating module in accordance with some suitable embodiments disclosed herein. In practice, the heating module may be operatively coupled to the exhaust system of the semiconductor processing tool 100 shown in FIGS. 1A and 1B. As shown, the heating module may include a supply line 200, a first valve 202, a second valve 204, a flow switch 206, a pressure gauge and/or sensor 208, a flow meter and/or sensor 210, a temperature sensor 212, a heating element 214 (as also shown in FIG. 3), a power supply 216, a thermally insulating jacket 218 and a controller 220. In general, the heating module selectively provides a flow of heated gas into the main pumping line 120 of the exhaust system, for example, to inhibit and/or 214 mitigate against the deposit and/or build-up of contaminated within the main pumping line 120.

In some suitable embodiments, the supply line 200 connected and/or operatively coupled at a first end thereof to a supply of gas to selectively receive a gas therefrom. For example, the gas provided to the supply line 200 from the supply may be nitrogen or another suitable inert gas. In some suitable embodiments, a second end of the supply line 200 is connected and/or operatively coupled to the main pumping line 120. As shown, the second end of the supply line 200 may be connected to and/or operatively coupled to the main pumping line 120 at a location downstream from the throttle valve 145 and upstream from a diverter tube 122. In some suitable embodiments, the second end of the supply line 200 may be connected to and/or operatively coupled to the main pumping line 120 at a location downstream from where the chuck vacuum line 125 connects and/or couples to the main pumping line 120. Suitably, the supply line 200 is connected and/or operatively coupled to the main pumping line 120 upstream from the diverter tube and/or over or opposite the port, which advantageously can avoid a potential gas kickback.

In some suitable embodiments, the first valve 202 regulates a rate of flow of a heated gas through the supply line 200 into the main pumping line 120. For example, the first valve 202 may be a needle valve or the like. Suitably, operation of the first valve may be automatically controlled by the controller 220. In some suitable embodiments, the rate of flow of heated gas through the supply line 200 may be measured, monitored, sensed and/or detected by the flow meter and/or sensor 210. In practice, the flow meter and/or sensor 210 may provide a signal to the controller 220 indicating the rate of flow of heated gas through the supply line 200. In turn, the controller 220 may automatically control and/or adjust the first valve 202 in response to the received signal to achieve a desired or set rate of flow of the heated gas through the supply line 200 and into the main pumping line 120.

In some suitable embodiments, the second valve 204 is controlled, for example, automatically by the controller 220, to selectively begin and end a flow of the heated gas from the supply line 200 into the main pumping line 120 in coordination with the semiconductor fabrication process being conducted with the semiconductor processing tool 100. For example, the second valve 204 may be a pneumatic valve or the like. In practice, the second valve may be selectively opened and closed to begin and end respectively the flow of heated gas into the main pumping line 120 from the supply line 200.

In some suitable embodiments, the flow switch 206 may be a normally open flow switch allowing for a free flow of gas through the supply tube 200. In practice, the flow switch may be closed to inhibit gas flow through the supply line 200, for example, under the automatic control of the controller 220 to protect the gas supply when established conditions are detected by the controller 220 and the controller 220 determines that the gas supply should be protected by closing the flow switch.

In some suitable embodiments, the heating element 214 is contained within the supply line 200. For example, in some suitable embodiments, the heating element 214 may be a halogen lamp. In some suitable embodiments, the heating element 214 has a helical shape, for example, as shown in FIG. 3. The shape and/or arrangement of the heating element 214 within the supply line 200 has an advantage of providing direct and/or efficient heating to the gas flowing within the supply line 200 over, through, past and/or around the heating element 214. In some suitable embodiments, the supply line 200 (or at least the portion or section thereof containing the heating element 214) may be constructed of stainless steel tube or another suitable metal tubing or the like. In practice, one or more Teflon or polytetrafluoroethylene (PTFE) or other suitable o-rings or other heat resistant gaskets or the like may be used to create suitable seals between respective components of the heating module, for example, between sections of the supply line 220 and in particular between a section of the supply line 200 containing the heating element 214 the sections of the supply line 200 adjacent thereto. In some suitable embodiments, a thermally insulating blanket or jacket 218 may be wrapped and/or otherwise arranged around an outside of the supply line 200 at or near a location where the heating element 214 is contained within the supply line 200. In practice, the blanket or jacket 218 may be constructed of a cotton, Teflon, PTFE or other suitable heat-resistant and/or thermally insulating material and/or cloth, and/or combination thereof. Use of the thermally insulating blanket and/or jacket 218 in this way has an advantage of making the heating module more efficient by mitigate against a loss of heat generated by the heating element 214 through the walls of the supply line 200.

In some suitable embodiments, the heating element 214 is connected and/or operatively coupled to a power supply 216 that selectively supplies power to and/or energizes the heating element 214 to selectively generate heat therefrom so as to selectively heat the gas flowing through the supply line 200 before it is injected into the main pumping line 120. In practice, the power supply may be automatically controlled by the controller 220. Suitably, the temperature sensor 212 may measure, monitor, sense and/or detect a temperature of the gas flowing within the supply line 200, for example, at or near a location of the heating element 214 or just downstream therefrom, and in turn provide a signal to the controller 220 indicating the same. In response to the signal received from the temperature sensor 212, the controller may in turn control and/or adjust the power supply 216 to suitably and/or selective energize the heating element 214. In some suitable embodiments, the controller 220 controls the power supply 216 in order to energize the heating element 214 such that the gas is heated and/or maintained by the heating element 214 to and/or at a temperature in a range of between about 105° C. and about 110° C., inclusive.

As mentioned above, the flow meter and/or sensor 210 may measure, monitor, sense and/or detect the rate of flow of gas through the supply line 200 and in turn provide a signal to the controller 220 indicating the same. In some suitable embodiments, the pressure gauge and/or sensor 208 may measure, monitor, sense and/or detect the pressure within the supply line 200 and in turn provide a signal to the controller 220 indicating the same. Based on the signals received from the pressure gauge and/or sensor 208 and the flow meter and/or sensor 210, the controller 220 may detect and/or determine that there is no gas or an insufficient amount of gas being supplied and/or available from the gas supply based on the signals received by the controller 220. Under such circumstances, the controller 220 may automatically cut, interrupt, limit and/or otherwise suspend the supply of power from the power supply 216 to the heating element 214. This has an advantage of not generating heat from the heating element 214 when there is no gas or an insufficient amount of gas flowing through the supply line 200 and/or when there is no gas or an insufficient supply of gas available from the gas supply, thereby protecting the heating module from overheating which can potentially cause damage to the heating module, the exhaust system, the semiconductor processing tool 100 and/or components thereof.

In the following, some further illustrative embodiments are described.

In some embodiments, a semiconductor processing tool includes: a process chamber into which a semiconductor wafer is loaded for conducting a semiconductor fabrication process with the tool; a support contained in the process chamber, the support selectively securing thereto the semiconductor wafer loaded into the process chamber for processing by the tool; a gas inlet system which selectively introduces a first gas into the process chamber in connection with processing the semiconductor wafer in the process chamber; and an exhaust system that selectively exhausts gas from the process chamber. Suitably, the exhaust system includes: a first line coupled to the process chamber through which gas is exhausted from the process chamber; and a pump coupled to the first line to selectively draw gas through the first line from the process chamber. The tool further includes a heating module having: a second line coupled to the first line and a supply of a second gas, wherein the second gas is selectively flowed through the second line from the supply into the first line; and a heating element contained in the second line, the heating element being selectively energized to heat the second gas flowing in the second line before the second gas is flowed from the second line into the first line.

In some further embodiments, the heating module further includes at least one of: a flow switch that is selectively opened and closed to selectively permit and block respectively a flow of gas through the second line; a first valve that regulates a rate of flow of the second gas through the second line into the first line; a flow meter that measures a rate of flow of gas through the second line; a pressure sensor that measures a pressure within the second line; and a temperature sensor that measures a temperature of the second gas within the second line.

In still additional embodiments, the heating module further includes: a power supply that selectively energizes the heating element to generate heat therefrom.

In some further embodiments, the heating module further includes: a controller, the controller controlling at least one of the flow switch, the first valve and the power supply in response to a received signal from at least one of the flow meter, the pressure sensor and the temperature sensor.

In yet further embodiments, the controller controls the power supply such that the heating element is not energized when an insufficient flow of the second gas from the supply is detected in the second line.

In some further embodiments, the heating module further includes: a thermally insulting jacket wrapped around the second line at a location of the heating element within the second line.

In some embodiments, the second gas is nitrogen.

In yet further embodiments, the heating module heats the second gas to a temperature in a range of between 105° C. and 110° C., inclusive.

In some embodiments, the heating element is a halogen lamp.

In still further embodiments, the heating module further includes: a valve that is automatically controlled to selectively begin and end a flow of the second gas from the second line into the first line in coordination with the semiconductor fabrication process being conducted with the tool.

In yet additional embodiments, a method of semiconductor fabrication includes: loading a semiconductor substrate into a process chamber of a semiconductor processing tool; securing the semiconductor substrate with a vacuum chuck housed in the process chamber; introducing process gas into the process chamber in connection with a semiconductor fabrication process being performed on the semiconductor substrate within the process chamber; pumping exhaust gas from the process chamber through an exhaust pipe; obtaining an inert gas from a gas supply via a supply line coupled to the gas supply at a first end of the supply line, the supply line being coupled to the exhaust pipe at a second end of the supply line; heating the inert gas within the supply line; and automatically controlling a first valve to selectively begin and end a flow of the heated inert gas into the exhaust pipe from the supply line in coordination with the semiconductor fabrication process.

In some further embodiments, the heating is performed from within the supply line by a heating element contained within the supply line.

In some additional embodiments, the method further includes: measuring a temperature of the inert gas within the supply line; and automatically controlling the heating element in response to the measuring.

In some embodiments, the method further includes: measuring a rate of flow of the inert gas within the supply line; and automatically controlling a second valve to regulate the rate of flow in response to the measuring.

In some embodiments, the method further includes: detecting an insufficient flow of the inert gas from the supply within the supply line; and suspending the heating in response to the detecting.

In some further embodiments, the method further includes: monitoring a pressure within the supply line.

In still further embodiments, a heating module is operatively coupled to an exhaust pipe through which exhaust gas is pumped from a process chamber of a semiconductor processing tool. Suitably, the heating module includes: a supply line having an end thereof coupled to the exhaust pipe, which supply line selectively supplies a flow of nitrogen gas into the exhaust pipe; a helical shaped heating element contained within the supply line, which helical shaped heating element is operable to selectively heat the nitrogen gas as it flows through the supply line over the helical shaped heating element; a thermally insulating wrap arranged around an outside of the supply line at a location of the helical shaped heating element within the supply line; a pneumatic valve which is selectively openable and closable to begin and end respectively the flow of nitrogen gas into the exhaust pipe from the supply line; and a needle valve which is selectively operable to regulate a rate of flow of the nitrogen gas through the supply line.

In yet further embodiments, the heating module further includes a power supply operatively coupled to the helical shaped heating element, which power supply selectively provides power to the helical shaped heating element to selectively generate heat therefrom.

In still one more embodiment, the heating module further includes a controller that automatically controls operation of at least one of the pneumatic valve, the needle valve and the power supply in coordination with a semiconductor fabrication process conducted in the process chamber of the semiconductor processing tool.

In yet another embodiment, heated nitrogen gas flowed into the exhaust pipe from the heating module mitigates against a build-up of contaminates within the exhaust pipe.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing tool comprising:
a process chamber into which a semiconductor wafer is loaded for conducting a semiconductor fabrication process with the tool;
a support contained in the process chamber, the support selectively securing thereto the semiconductor wafer loaded into the process chamber for processing by the tool;
a gas inlet system which selectively introduces a first gas into the process chamber in connection with processing the semiconductor wafer in the process chamber;
an exhaust system that selectively exhausts gas from the process chamber, the exhaust system including:
a first line coupled to the process chamber through which gas is exhausted from the process chamber; and
a pump coupled to the first line to selectively draw gas through the first line from the process chamber; and
a heating module including:
a second line coupled to the first line and a supply of a second gas, wherein the second gas is selectively flowed through the second line from the supply into the first line; and
a heating element contained in the second line, the heating element being selectively energized to heat the second gas flowing in the second line before the second gas is flowed from the second line into the first line.

2. The semiconductor processing tool of claim 1, wherein the heating module further comprises at least one of:
a flow switch that is selectively opened and closed to selectively permit and block respectively a flow of gas through the second line;
a first valve that regulates a rate of flow of the second gas through the second line into the first line;
a flow meter that measures a rate of flow of gas through the second line;
a pressure sensor that measures a pressure within the second line; and
a temperature sensor that measures a temperature of the second gas within the second line.

3. The semiconductor processing tool of claim 2, wherein the heating module further comprises:
a power supply that selectively energizes the heating element to generate heat therefrom.

4. The semiconductor processing tool of claim 3, wherein the heating module further comprises:
a controller, the controller controlling at least one of the flow switch, the first valve and the power supply in response to a received signal from at least one of the flow meter, the pressure sensor and the temperature sensor.

5. The semiconductor processing tool of claim 4, wherein the controller controls the power supply such that the heating element is not energized when an insufficient flow of the second gas from the supply is detected in the second line.

6. The semiconductor processing tool of claim 1, wherein the heating module further comprises:
a thermally insulting jacket wrapped around the second line at a location of the heating element within the second line.

7. The semiconductor processing tool of claim 1, wherein the second gas is nitrogen.

8. The semiconductor processing tool of claim 1, wherein the heating module heats the second gas to a temperature in a range of between 105° C. and 110° C., inclusive.

9. The semiconductor processing tool of claim 1, wherein the heating element is a halogen lamp.

10. The semiconductor processing tool of claim 1, wherein the heating module further comprises:
a valve that is automatically controlled to selectively begin and end a flow of the second gas from the second line into the first line in coordination with the semiconductor fabrication process being conducted with the tool.

11. A method of semiconductor fabrication comprising:
loading a semiconductor substrate into a process chamber of a semiconductor processing tool;
securing the semiconductor substrate with a vacuum chuck housed in the process chamber;
introducing process gas into the process chamber in connection with a semiconductor fabrication process being performed on the semiconductor substrate within the process chamber;
pumping exhaust gas from the process chamber through an exhaust pipe;
obtaining an inert gas from a gas supply via a supply line coupled to the gas supply at a first end of the supply line, the supply line being coupled to the exhaust pipe at a second end of the supply line;
heating the inert gas within the supply line; and
automatically controlling a first valve to selectively begin and end a flow of the heated inert gas into the exhaust pipe from the supply line in coordination with the semiconductor fabrication process.

12. The method of claim 11, wherein the heating is performed from within the supply line by a heating element contained within the supply line.

13. The method of claim 12, further comprising:
measuring a temperature of the inert gas within the supply line; and
automatically controlling the heating element in response to the measuring.

14. The method of claim 11, further comprising:
measuring a rate of flow of the inert gas within the supply line; and
automatically controlling a second valve to regulate the rate of flow in response to the measuring.

15. The method of claim 11, further comprising:
detecting an insufficient flow of the inert gas from the supply within the supply line; and
suspending the heating in response to the detecting.

16. The method of claim 15, further comprising:
monitoring a pressure within the supply line.

17. A heating module operatively coupled to an exhaust pipe through which exhaust gas is pumped from a process chamber of a semiconductor processing tool, the heating module comprising:
a supply line having an end thereof coupled to the exhaust pipe, which supply line selectively supplies a flow of nitrogen gas into the exhaust pipe;
a helical shaped heating element contained within the supply line, which helical shaped heating element is operable to selectively heat the nitrogen gas as it flows through the supply line over the helical shaped heating element;
a thermally insulating wrap arranged around an outside of the supply line at a location of the helical shaped heating element within the supply line;
a pneumatic valve which is selectively openable and closable to begin and end respectively the flow of nitrogen gas into the exhaust pipe from the supply line; and
a needle valve which is selectively operable to regulate a rate of flow of the nitrogen gas through the supply line.

18. The heating module of claim 17, further comprising:
a power supply operatively coupled to the helical shaped heating element, which power supply selectively provides power to the helical shaped heating element to selectively generate heat therefrom.

19. The heating module of claim 18, further comprising:
a controller that automatically controls operation of at least one of the pneumatic valve, the needle valve and the power supply in coordination with a semiconductor fabrication process conducted in the process chamber of the semiconductor processing tool.

20. The heating module of claim 19, wherein heated nitrogen gas flowed into the exhaust pipe from the heating module mitigates against a build-up of contaminates within the exhaust pipe.
